(19) United States
(12) Patent Application Publication
(10) Pub. No.: US 2008/0286692 A1
(43) Pub. Date: Nov. 20, 2008

(54) Photosensitve Laminate

(76) Inventor: Toshifumi Komatsu, Duluth, MN (US)

Correspondence Address: PAULY, DEVRIES SMITH & DEFFNER, L.L.C., Plaza VII-Suite 3000, 45 South Seventh Street, MINNEAPOLIS, MN, 55402-1630, US

(21) Appl. No.: 11/911,851

(22) PCT Filed: Apr. 21, 2006
(86) PCT No.: PCT/US06/15324

§ 371 Date: May 7, 2008

Related U.S. Application Data
(60) Provisional application No. 60/674,134, filed on Apr. 21, 2005.

(51) Int. Cl. G03F 7/004; B32B 7/12

(52) U.S. Cl. 430/287.1; 430/270.1; 428/354; 428/480

(57) ABSTRACT

A photoresist laminate structure comprising at least one photosensitive resist layer and a polymeric layer bound to the photosensitive resist layer is disclosed, wherein the polymeric layer is substantially impermeable to water.

This application is being filed as a PCT International Patent application on 21 Apr., 2006, in the name of Ikonics Corporation, a U.S. national corporation, applicant for the designation of all countries except the U.S., and Toshifumi Komatsu, a citizen of Japan, applicant for the designation of the U.S. only, and claims priority to U.S. Patent Application Ser. No. 60/674,134 filed on 21 Apr., 2005.

### BACKGROUND OF THE INVENTION

Photosensitive resists have been used for abrasive etching purposes for many years. However, most photosensitive resists do not have adequate durability to etch deeply into hard substrates, such as stone surfaces. Although it is possible to increase the thickness of a resist to provide enhanced durability, thicker resists often have less precise patterns, are more difficult to expose and develop, can be more difficult to apply, and require larger quantities of materials, which can drive up costs. Therefore, a need exists for an improved photosensitive resist that permits deep etching into hard surfaces.

In addition, it is sometimes necessary to use photosensitive resists for abrasive etching in exposed conditions where environmental conditions are difficult to control. For example, abrasive etching of tombstones is sometimes undertaken directly within a cemetery, such as to etch the name or date of death of an individual who is sharing a tombstone with their spouse. Such conditions often involve etching onto a cool, wet, or damp surface. Therefore, a further need exists for an improved photosensitive resist that permits etching in conditions with limited environmental controls.

### SUMMARY OF THE INVENTION

The present invention is directed to a photoresist laminate suitable for use in abrasive etching, in particular abrasive etching of relatively hard substrates, such as stone used in monuments. In addition, the present invention is particularly well suited to uses in which the laminate will be applied in a moist environment, such on exterior stone surfaces.

The photoresist laminates made in accordance with the present invention include a photoresist layer adhered to a water resistant polymeric sheet. This polymeric sheet, optionally made of polyester or similar materials, provides support for the photoresist layer and also keeps the photoresist layer from getting too dry or too wet when applied to a substrate that will be etched. Thus, this polymeric sheet is remains part of the laminate when the laminate is placed on the substrate. The polymeric sheet is generally thin enough that it can be pierced by aggressive exposure to particulates during the etching process, and thus those portions of the polymeric sheet not protected by the photoresist layer are blasted away during the etching process.

The above summary of the present invention is not intended to describe each disclosed embodiment of the present invention. This is the purpose of the figures and the detailed description that follow.

### DRAWINGS

Other aspects and advantages of the invention will become apparent upon reading the following detailed description and upon reference to the drawing in which:

FIG. 1 is a cross sectional view of a laminate constructed and arranged in accordance with the invention.

FIG. 2 is a cross sectional view of a laminate constructed and arranged in accordance with the invention, after the laminate has been placed on a substrate to be abrasively etched.

FIG. 3 is a cross-sectional view of a laminate constructed and arranged in accordance with the invention, after the substrate has been abrasively etched.

While the invention is susceptible to various modifications and alternative forms, specifics thereof have been shown by way of example in the figure and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present invention is directed to a photoresist laminate suitable for use in abrasive etching, in particular abrasive etching of hard substrates, such as stone used in monuments. In addition, the present invention is particularly well suited to uses in which the laminate will be applied in a moist environment, such on exterior stone surfaces.

Photoresist laminates made in accordance with the present invention include a photoresist layer adhered to a water resistant polymeric sheet. This polymeric sheet, optionally made of polyester or similar materials, provides support for the photoresist layer and also keeps the photoresist layer from getting too dry or too wet when applied to a substrate that will be etched. Thus, this polymeric sheet is applied to the substrate when the laminate is placed on the substrate. The polymeric sheet is generally thin enough that it can be pierced by aggressive exposure to particulates during the etching process, and thus those portions not protected by the photoresist layer are blasted away during the etching process.

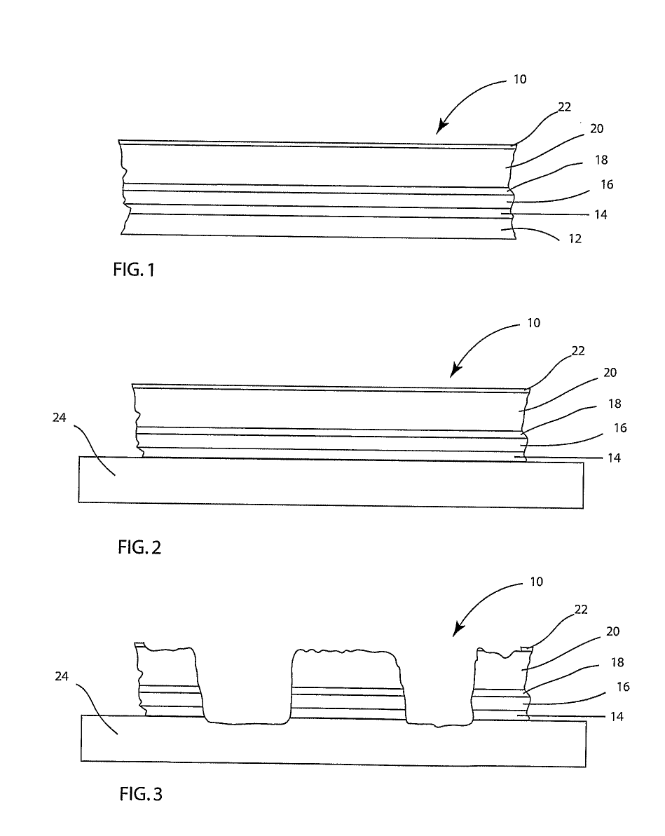

Referring now to FIGS. 1 to 3, an example of a photoresist laminate 10 made in accordance with an implementation of the invention is shown, the laminate 10 is depicted prior to placement on a substrate. The laminate 10 includes a carrier layer 12, such as a silicone-treated polyester sheet. The carrier layer 12 can be, for example about 2 mils thick, optionally thinner or thicker. Carrier layer 12 is sufficiently strong to provide ready positioning and repositioning of the photoresist laminate 10, yet can be removed from the laminate to expose a pressure sensitive adhesive layer 14. This pressure sensitive adhesive layer 14 is typically water resistant and insoluble or substantially insoluble in water, allowing the laminate 10 to be adhered to moist substrates 24. In use the carrier layer 12 is removed from the laminate 10 to expose the pressure sensitive adhesive layer 14, which is then placed in contact with the substrate 24 (such as a granite slab).

In the embodiment shown, a water resistant sheet 16 is positioned adjacent of adhesive layer 14. This water resistant sheet 16 can be, for example, a layer of polyester approximately 0.5 mils thick. The purpose of water resistant sheet 16 is to help preserve the integrity of photosensitive main layer 20, both by helping physically support the photosensitive layer 20 as well as to keep the photosensitive main layer 20 relatively dry when the substrate 24 is moist. In certain embodiments an adhesive sub-layer 18 containing a pressure sensitive adhesive and non-sliding sub-layer components is positioned between the water resistant sheet 16 and the photosensitive layer 20. This sub-layer holds the sheet 16 and photosensitive layer 20 together, and also prevents them from sliding with regard to one another.

Thus, the photosensitive layer 20 is positioned on top of the sub-layer 18. Suitable materials for the photosensitive main layer 20 include PBV, and suitable thicknesses include approximately 10 mils. It will be appreciated that various additional layers can be used, and that individual layers can be divided into sub-layers, such as by having a photosensitive layer with two or more sub-layers.

In the embodiment depicted, an anti-blocking topcoat layer 22 is placed on top of the main layer 20. Various formulations suitable for the present invention are shown below:

### Pressure Sensitive Adhesive (Layer 14)

Suitable pressure sensitive adhesives for layer 14 include, but are not limited to, PS-6776 from Clifton Adhesive.

### Water Resistant Layer (Sheet 16)

Suitable materials for water resistant sheet 16 include, but are not limited to, the following: 64 Gauge Lumirror FA4 from Toray. The water resistant sheet 16 should be constructed such that it helps prevent excessive transmission of moisture into the photosensitive layer 20, yet is readily blastable by a strong stream of abrasives.

### Adhesive Sub-Layer (Layer 18)

Suitable materials for adhesive sub-layer 18 include, but are not limited to, the following composition, which is a mixture of:

| | Percent |
|---|---|
| Flexbond 150 (Air Products) | 88.64 |
| Water | 8.81 |
| Silwet L-700 1 (GE Silicones) | 0.03 |
| Silwet L-7604 (GE Silicones) | 0.01 |
| Nopco 227 1 (Fitz Chem Corporation) | 0.33 |
| WC-0665-EN-770 (HB Fuller) | 0.50 |
| Aquastik 1120 | 1.68 |
| Total | 100 |

### Photoresist (Layer 20)

Suitable materials for the photoresist layer 20 include, but are not limited to, the following composition, which is a mixture of

| | Percent |
|---|---|
| 5401SBQ (Ikonics Corporation) | 30.00 |
| Zonyl FSO (3M) | 0.11 |
| Unisperse Red RSB-PI (The Chidley & Peto Company) | 0.20 |
| IPA | 1.58 |
| AirFlex 400 (AirProducts) | 61.30 |
| PN3 17 82 (HB Fuller) | 6.81 |
| | 100.00 |

### Topcoat Layer (Layer 22)

Suitable materials for the top coat layer 22 include, but are not limited to, the following composition, which is a mixture of:

| | Percent |
|---|---|
| Slip-Ayd SL-300 (Elementis) | 42.60 |
| PVA 205 (DuPont) | 34.07 |
| Water | 23.33 |
| | 100.00 |

More generally, and in the alternative, the film or support layer of the invention comprises a web, film or other relatively thin substrate, which can be coated with the photosensitive compositions of the invention. This film or substrate layer must be mechanically strong to permit rapid coating manufacture of the resist 5 laminate, but can also be processable in typical exposure processing and imaging environments of use of the invention. Preferred sheet-like film or support layers can comprise transparent films, i.e. a thickness of about 0.05 to 0.3 mm (2 to 12 mils) and can be made from a variety of natural or synthetic materials including treated cellulose, paper, polyolefin resins, polyester resins, polyvinylchloride resins, etc. The photosensitive layer generally comprises either negative or positive photosensitive or photoresist materials. Negative working photoresist compositions typically interact with light to transform the composition from the soluble state to a substantially less soluble film. Positive working photoresist compositions are transferred from an insoluble state to a soluble state. Typically resist compositions contain reactive monomeric and/or polymeric substances along with photoactivated initiators.

A first mode of operation of the photosensitive structure of the invention involves negative resist processing. In such processing, substances in the photoresist can react polymerize or crosslink when exposed to a sufficient quantity of actinic radiation of an appropriate wavelength to activate the reactive components of the resist photosensitive layers. In a typical formulation, the electromagnetic radiation is typically absorbed by the photosensitive polymer, photoactivators or initiators that initiate or participate in polymerization or crosslinking in the photosensitive layer. Such reactions typically render the photosensitive material where exposed less soluble or substantially less soluble to the action of solvents including water, alcohols, hydrocarbons, chlorinated hydrocarbons, etc. In the first layer, the radiation renders the entire first layer relatively less soluble when compared to the second layer.

The preferred photosensitive compositions contain a polymerizable or crosslinkable polymeric composition in a formulation with a polymeric material. The photoresist compositions can optionally contain other functional materials including surfactants, defoamers, dyes antioxidants and other additives that can aid in the formation of a thin uniform layer without holes, thin spots or other variations in the thin uniform layer. Crosslinkable polymers can inherently crosslink with other reactive components or can crosslink with a separate crosslinking agent resulting in substantial insolubility of the crosslink polymer structure. Such crosslinking results in a film of reduced solubility that can be transferred to the surface of an object for image formation. Further, the crosslinking can be used to form the integral membrane of the invention.

Useful crosslinkable polymer compositions comprise polymers having sufficient pendant hydroxyl groups to react with sufficient concentration of a photoinitiator/crosslinking species. Such polymers can generically be considered homopolymers or copolymers of partially or fully saponified polyvinylacetate. Such materials are commonly made by polymerizing vinyl acetate and removing acetyl groups leaving the pendant hydroxyls. In this way, homopolymers and copolymers 15 can be made by polymerizing vinyl acetate with a variety of ethylenically unsaturated monomers to form the polymer for later saponification.

Such polyvinyl alcohol homopolymers and copolymers can also be used as film forming agents in forming photosensitive layers using other species as crosslinkable materials. The final polyvinyl alcohol polymers and copolymers are characterized by molecular weight and degree of hydrolysis. The common molecular weights of commercial polyvinyl alcohol materials are reflected in the viscosity of a 4 wt % solution measured in centipoise (cP) at 20° C. with a Brookfield viscometer. The viscosity of a 4 wt % solution can range from about 5 to about 65 cP.

Another class of useful photocrosslinkable materials include diazonium salt photocrosslinking compositions. Diazonium salt crosslinkers, when contacted by typically ultraviolet light, yield one molecule of nitrogen per diazonium group and generate active crosslinking nitrogen containing species. Suitable diazonium photoinitiated crosslinkers include para-diazodiphenylamine chloride—0.5 zinc 30 chloride—formaldehyde condensates, para-diazodiphenylamine sulfate—formaldehyde condensate, tetrazonium salts, etc. (see Tsunoda and Yamaoka, J. Appl. Poly. Sci., Vol. 8, pp. 1379-1390 (1964)).

The photoresist compositions of the invention can further include a film forming polymeric binding agent. During photocrosslinking of the composition, the 5 binding agent is entrapped in a mesh formed by the polymerizing or crosslinking polymeric materials. In this way the binding agent adds to the insolubility on the film forming potential of both the first layer forming the integral membrane and in the second layer forming the image. Typically, polymeric binding agents comprise relatively water insoluble polymers that can be formed into latices or stable 10 suspensions of small particles in the polymer composition in water or aqueous media. Such polymer suspensions are well known in the art and available from a number of suppliers.

Suitable binding agents used in the invention include carboxymethyl cellulose, partially hydrolyzed polyvinyl alcohols, water insoluble homopolymers 15 and copolymers made of comonomers such as styrene, methylmethacrylate, vinyl acetate, vinyl butyl, vinyl pyrrolidone, ethylene, propylene, alkylene oxide monomers and other monomers. Preferred polymeric binding agents comprise polyvinyl acetates for reasons of compatibility with polyvinyl alcohol polymers, the economy and stability of their suspensions in aqueous media. Such polymer 20 compositions are broadly available from a variety of manufacturers. The photoresist compositions can contain plasticizer components that can help in providing resiliency and adhesion to the layers, can permit the layers to resist flaking and delamination during use.

Sensitizers commonly used in photopolymerizable materials requiring sensitizers are typically monomeric materials that can absorb light radiation for activating ethylenically unsaturated groups. Said groups are vinyl, acroyl, methacroyl, allyl, vinyl ether, acrylamido, etc. Groups or prepolymers thereof having an average degree of unsaturated saturation between about 1 and 5. These materials are well known and used in the art and include acrylamide acrylic acid, methacrylic acid, ethylmethacrylate, methylmethacrylate, methylolacrylamide, etc. Preferred polyfunctional sensitizers having two or more photosensitive ethylenically unsaturated groups include such sensitizers as pentaerythritol triacrylate, pentaerythritol tetracrylate and related di-, tri-, or tetraunsaturated pentaerythritol derivatives, trialylisocyanurate and others.

Typically the aqueous photocrosslinkable resist composition contains about 0.1 to about 75 wt %, preferably about 5 to 35 wt % of a photocrosslinkable or photopolymerizable composition that can be crosslinked using a sensitizer or is selfcrosslinking. In the case the material is crosslinked using a sensitizer, a polyvinyl alcohol polymer is used in amounts of about 20 to 75 wt %, preferably about 25 to 45 wt %. In the case of a self-crosslinking material containing a styrylpyridinium group or a diazo group, the aqueous resist composition can contain about 3 to about 40 wt % of such a material. Regardless of the mode of crosslinking, the resist can contain a film forming polymeric binder, optionally a plasticizer and other materials such as a surfactant, a defoamer, a dye, an antioxidant, a perfume or other functional materials.

The foregoing description, examples, methods of use and other disclosures in the specification provide a basis for understanding the laminate materials and the operation of the invention. However, since many embodiments of the invention can be made without departing from the spirit or scope of the invention, the invention resides in the claims hereinafter appended.

We claim:

1. A photoresist laminate structure comprising:
at least one photosensitive resist layer; and
a polymeric layer bound to the photosensitive resist layer;
wherein the polymeric layer is substantially impermeable to water.

2. The photoresist laminate structure of claim 1, wherein the polymeric layer comprises polyester.

3. The photoresist laminate structure of claim 1, further comprising a carrier layer.

4. The photoresist laminate structure of claim 2, wherein the carrier layer comprises polyester, biaxially oriented polypropylene, high density polyethylene, low density polyethylene, or other polymer films.

5. The photoresist laminate structure of claim 1, wherein the photosensitive layer comprises a photo crosslinked, aqueous developed polyvinyl alcohol-based polymeric resin.

6. The photoresist laminate structure of claim 1, wherein the photosensitive layer comprises from 1 to 40 weight percent of a polymeric photosensitive resin and from 30 to 98 weight percent of a polyvinyl acetate based upon the total dry weight of the photosensitive layer.

7. A photoresist laminate structure comprising:
at least one photosensitive resist layer; and
a polymeric layer bound to the photosensitive resist layer;
an adhesive layer joining the photosensitive resist layer and the polymeric layer.

8. The photoresist laminate structure of claim 7, further comprising a pressure sensitive adhesive layer bound to the polymeric layer, said pressure sensitive adhesive layer configured to bond the laminate to a substrate to be abrasively etched.

9. The photoresist laminate structure of claim 7, further comprising a carrier layer.

10. The photoresist laminate structure of claim 7, wherein the polymeric layer comprises polyester.
